(19) United States
(12) Patent Application Publication
(10) Pub. No.: US 2026/0089837 A1
(43) Pub. Date: Mar. 26, 2026

(54) CIRCUIT STRUCTURE AND MANUFACTURING METHOD THEREOF

(71) Applicant: SILICONWARE PRECISION INDUSTRIES CO., LTD., Taichung City (TW)

(72) Inventors: Chung-Chih YEN, Taichung City (TW); Chun-Chu LAI, Taichung City (TW)

(73) Assignee: SILICONWARE PRECISION INDUSTRIES CO., LTD., Taichung City (TW)

(21) Appl. No.: 19/212,814

(22) Filed: May 20, 2025

(30) Foreign Application Priority Data
Jun. 7, 2024 (TW) 113121347

(51) Int. Cl. H05K 1/02; H05K 3/06; H05K 3/18

(52) U.S. Cl. CPC H05K 1/0298; H05K 3/06; H05K 3/188; H05K 2201/0347

(57) ABSTRACT

A circuit structure and a manufacturing method thereof are provided, in which a seed layer composed of a plurality of discontinuous metal blocks is formed on a dielectric layer, and a circuit layer is formed on the seed layer by electroplating. By roughening the overall surface of the plurality of discontinuous metal blocks and creating a relatively concave-convex structure, the bonding effect between the seed layer and the circuit layer formed thereon is strengthened, thereby preventing the problem of delamination and improving the process yield.

### BACKGROUND

### 1. Technical Field

The present disclosure relates to a semiconductor manufacturing process, and more particularly, to a circuit structure and a manufacturing method thereof.

### 2. Description of Related Art

With the vigorous development of the electronics industry, electronic products are becoming thinner, lighter and smaller in shape, and their functions are being developed towards high performance, high functionality and high speed. Therefore, in order to meet the requirements of high integration and miniaturization of semiconductor devices, semiconductor chips and substrates are required to have high-density and fine-spacing circuit layers.

Furthermore, fan-out packaging technology has become an important trend in the development of fifth generation (5G) network technology and advanced packaging in the future. Redistribution layer (RDL) can realize more inputs/outputs (I/O) and thinner semiconductor devices, so it has become the development focus of the semiconductor industry.

The aforementioned RDL process mainly involves first laying a whole seed layer on a dielectric layer, and then electroplating a circuit layer on the seed layer by using the seed layer as a current conduction path. Thereafter, another dielectric layer and another circuit layer may be formed and stacked on the circuit layer in sequence to form a multi-layer RDL structure to meet the high integration and miniaturization requirements of semiconductor devices.

However, as the number of RDL layers increases, the problem of delamination due to stress between layers during the manufacturing process arises.

Therefore, how to overcome the above-mentioned drawbacks of the prior art has become an urgent issue to be solved.

### SUMMARY

In view of the various deficiencies of the prior art, the present disclosure provides a circuit structure, which comprises: a dielectric layer; a seed layer formed on the dielectric layer, wherein the seed layer is composed of a plurality of discontinuous metal blocks; and a circuit layer formed on the seed layer.

The present disclosure further provides a method of manufacturing a circuit structure, which comprises: providing a dielectric layer; forming a seed layer on the dielectric layer, wherein the seed layer is composed of a plurality of discontinuous metal blocks; and forming a circuit layer on the seed layer.

In the aforementioned circuit structure and method, spacings between the plurality of discontinuous metal blocks are the same; sizes of the plurality of discontinuous metal blocks are the same; spacings between the plurality of discontinuous metal blocks are different; or sizes of the plurality of discontinuous metal blocks are different.

In the aforementioned circuit structure and method, the circuit layer includes a plurality of conductive circuits, and each of the plurality of conductive circuits covers portions of the plurality of discontinuous metal blocks.

In the aforementioned circuit structure and method, the seed layer is formed by first forming a metal layer on the dielectric layer, and then etching the metal layer to form the plurality of discontinuous metal blocks.

In the aforementioned circuit structure and method, the seed layer is formed by directly forming the plurality of discontinuous metal blocks on the dielectric layer.

In the aforementioned circuit structure and method, the present disclosure further comprises: forming a patterned resist layer on the dielectric layer and the plurality of discontinuous metal blocks, wherein the patterned resist layer has a plurality of openings.

In the aforementioned circuit structure and method, the present disclosure further comprises: forming the circuit layer by electroplating on the plurality of discontinuous metal blocks exposed from the plurality of openings in the patterned resist layer.

In the aforementioned circuit structure and method, the present disclosure further comprises: removing the patterned resist layer and portions of the plurality of discontinuous metal blocks covered by the patterned resist layer.

In the aforementioned circuit structure and method, the present disclosure further comprises: forming another dielectric layer on the circuit layer; forming another seed layer composed of a plurality of another discontinuous metal blocks on the another dielectric layer; and forming another circuit layer on the another seed layer.

In the aforementioned circuit structure and method, the another circuit layer includes a plurality of another conductive circuits, and a line width/line spacing of each of the plurality of another conductive circuits is smaller than a line width/line spacing of each of the plurality of conductive circuits in the circuit layer.

In the aforementioned circuit structure and method, size and spacing of portions of the plurality of another discontinuous metal blocks under each of the plurality of another conductive circuits are smaller than size and spacing of portions of the plurality of discontinuous metal blocks under each of the plurality of conductive circuits.

As can be seen from the above, in the circuit structure and the manufacturing method thereof of the present disclosure, a seed layer composed of a plurality of discontinuous metal blocks is formed on the dielectric layer, and a circuit layer is formed by electroplating on the seed layer. By roughening the overall surface of the plurality of discontinuous metal blocks (the seed layer) and creating a relatively concave-convex structure, the bonding effect between the seed layer and the circuit layer formed thereon is strengthened, thereby preventing the conventional problem of delamination caused by stress between layers and improving the process yield.

### BRIEF DESCRIPTION OF THE DRAWINGS

FIG. 1A, FIG. 1B-1, FIG. 1C, FIG. 1D, and FIG. 1E are cross-sectional schematic views illustrating a method of manufacturing a circuit structure according to the present disclosure.

FIG. 1B-2 and FIG. 1B-3 are cross-sectional schematic views according to other embodiments of FIG. 1B-1.

FIG. 2 is a cross-sectional schematic view of a circuit structure according to another embodiment of the present disclosure.

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “another,” “other,” “a,” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

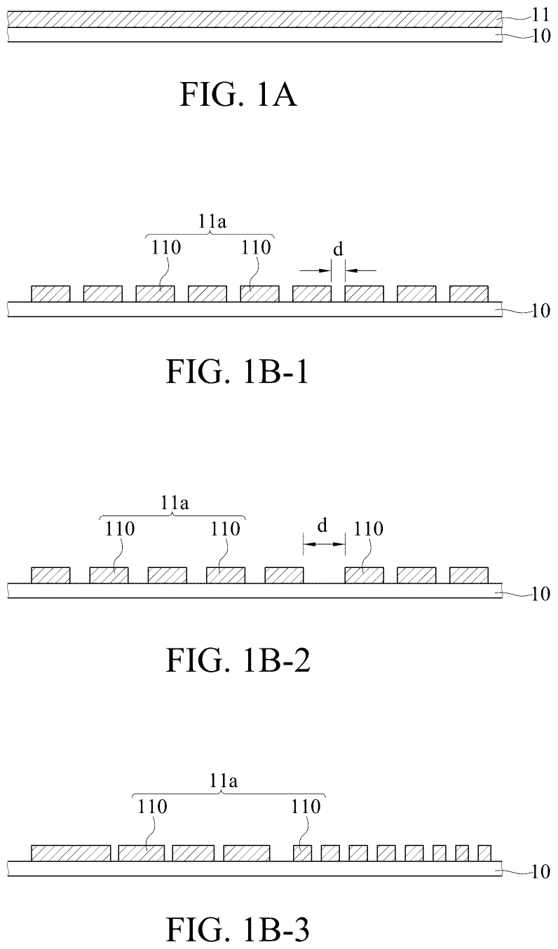

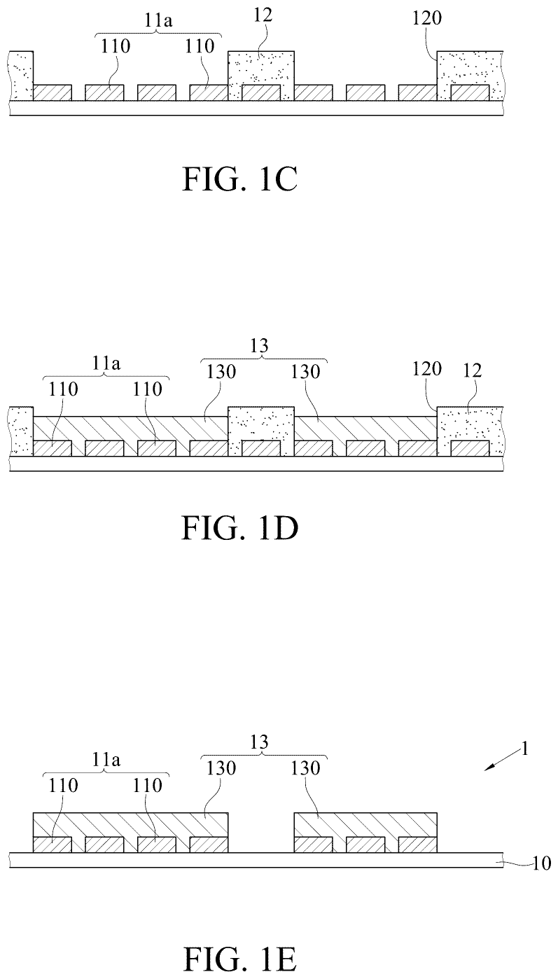

FIG. 1A, FIG. 1B-1, FIG. 1C, FIG. 1D, and FIG. 1E are cross-sectional schematic views illustrating a method of manufacturing a circuit structure 1 according to a first embodiment of the present disclosure.

As shown in FIG. 1A, a dielectric layer 10 is provided, and a whole metal layer 11 is applied to or formed on the dielectric layer 10.

The dielectric layer 10 is made of Ajinomoto build-up film (ABF), polybenzoxazole (PBO), polyimide (PI), prepreg (PP) having glass fiber, or other dielectric materials. The metal layer 11 is made of, for example, copper (the metal layer 11 is a seed layer in the prior art).

The metal layer 11 can be formed by a sputtering process, a physical vapor deposition (PVD) process, or other suitable processes.

As shown in FIG. 1B-1, an etching process (dry etching or wet etching) is performed on the metal layer 11 to form a plurality of discontinuous metal blocks 110. The plurality of discontinuous metal blocks 110 constitute the seed layer 11a of the present disclosure.

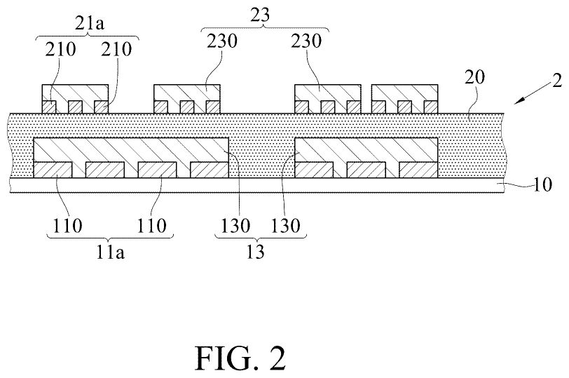

In one embodiment, spacings d (e.g., distances, gaps, or intervals) between the plurality of discontinuous metal blocks 110 can be the same, and sizes of the plurality of discontinuous metal blocks 110 can also be the same (e.g., the size of each of the plurality of discontinuous metal blocks 110 can be the same). In another embodiment, the spacings d between the plurality of discontinuous metal blocks 110 may be different (as shown in FIG. 1B-2). In yet another embodiment, the sizes of the plurality of discontinuous metal blocks 110 may be different (as shown in FIG. 1B-3).

In addition, in other embodiments, the step of FIG. 1A may be omitted, and a plurality of discontinuous metal blocks 110 may be directly formed on the dielectric layer 10 to serve as a seed layer 11a (as shown in FIG. 1B-1), for example, by doping methods such as ion implantation.

As shown in FIG. 1C, a patterned resist layer 12 is formed on the dielectric layer 10 and the plurality of discontinuous metal blocks 110 (the seed layer 11a). The patterned resist layer 12 has a plurality of openings 120 to expose portions of the plurality of discontinuous metal blocks 110 (the seed layer 11a).

As shown in FIG. 1D, the plurality of discontinuous metal blocks 110 (the seed layer 11a) are used as current conduction paths. A circuit layer 13 is formed by electroplating on the plurality of discontinuous metal blocks 110 (the seed layer 11a) that are exposed from the openings 120 in the patterned resist layer 12.

The circuit layer 13 includes a plurality of conductive circuits 130, wherein each of the conductive circuits 130 covers portions of the plurality of discontinuous metal blocks 110.

As shown in FIG. 1E, the patterned resist layer 12 and the portions of the plurality of discontinuous metal blocks 110 covered by the patterned resist layer 12 are removed to obtain the circuit structure 1 of the present disclosure, wherein the circuit structure 1 can be applied to circuits of semiconductor devices related to semiconductor chips, substrates, or interposers.

Please refer to FIG. 2, which is a cross-sectional schematic view of a circuit structure 2 according to another embodiment of the present disclosure, wherein another dielectric layer 20 is formed and stacked on the circuit layer 13 by continuously applying the redistribution layer (RDL) specification. Referring to the above-mentioned manufacturing method, another seed layer 21a composed of a plurality of discontinuous metal blocks 210 is formed on the another dielectric layer 20, and then another circuit layer 23 is formed on the another seed layer 21a.

In addition, more dielectric layers and circuit layers can be formed and stacked on the another circuit layer 23, and the seed layers between the stacked dielectric layers and circuit layers are composed of a plurality of discontinuous metal blocks.

Furthermore, the another circuit layer 23 can be electrically connected to the circuit layer 13 via a plurality of conductive blind vias (not shown) formed in the another dielectric layer 20.

In one embodiment, the another circuit layer 23 includes a plurality of another conductive circuits 230, wherein the line width/line spacing of each of the another conductive circuits 230 is smaller than the line width/line spacing of each of the conductive circuits 130, and the size and spacing of the portions of the plurality of discontinuous metal blocks 210 covered by and under each of the another conductive circuits 230 are smaller than the size and spacing of the portions of the plurality of discontinuous metal blocks 110 covered by and under each of the conductive circuits 130.

Via the above-mentioned manufacturing method, the present disclosure further provides a circuit structure 1, 2, which comprises: a dielectric layer 10; a seed layer 11a formed on the dielectric layer 10, wherein the seed layer 11a is composed of a plurality of discontinuous metal blocks 110; and a circuit layer 13 formed on the seed layer 11a.

The circuit layer 13 includes a plurality of conductive circuits 130, wherein each of the conductive circuits 130 covers portions of the plurality of discontinuous metal blocks 110.

The circuit structure 2 further comprises: another dielectric layer 20; another seed layer 21a formed on the another dielectric layer 20 and composed of a plurality of discontinuous metal blocks 210; and another circuit layer 23 formed on the another seed layer 21a.

In summary, in the circuit structure and the manufacturing method thereof of the present disclosure, a seed layer composed of a plurality of discontinuous metal blocks is formed on the dielectric layer, and a circuit layer is formed by electroplating on the seed layer. By roughening the overall surface of the plurality of discontinuous metal blocks (the seed layer) and creating a relatively concave-convex structure, the bonding effect between the seed layer and the circuit layer formed thereon is strengthened, thereby preventing the conventional problem of delamination caused by stress between layers and improving the process yield.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A circuit structure, comprising:
a dielectric layer;
a seed layer formed on the dielectric layer, and composed of a plurality of discontinuous metal blocks; and
a circuit layer formed on the seed layer.

2. The circuit structure of claim 1, wherein spacings between the plurality of discontinuous metal blocks are the same.

3. The circuit structure of claim 1, wherein sizes of the plurality of discontinuous metal blocks are the same.

4. The circuit structure of claim 1, wherein spacings between the plurality of discontinuous metal blocks are different.

5. The circuit structure of claim 1, wherein sizes of the plurality of discontinuous metal blocks are different.

6. The circuit structure of claim 1, wherein the circuit layer includes a plurality of conductive circuits, and each of the plurality of conductive circuits covers portions of the plurality of discontinuous metal blocks.

7. The circuit structure of claim 1, further comprising:
another dielectric layer;
another seed layer formed on the another dielectric layer and composed of a plurality of another discontinuous metal blocks; and
another circuit layer formed on the another seed layer.

8. The circuit structure of claim 7, wherein the another circuit layer includes a plurality of another conductive circuits, and a line width/line spacing of each of the plurality of another conductive circuits is smaller than a line width/line spacing of each of the plurality of conductive circuits in the circuit layer.

9. The circuit structure of claim 8, wherein size and spacing of portions of the plurality of another discontinuous metal blocks under each of the plurality of another conductive circuits are smaller than size and spacing of portions of the plurality of discontinuous metal blocks under each of the plurality of conductive circuits.

10. A method of manufacturing a circuit structure, comprising:
providing a dielectric layer;
forming a seed layer on the dielectric layer, wherein the seed layer is composed of a plurality of discontinuous metal blocks; and
forming a circuit layer on the seed layer.

11. The method of claim 10, wherein spacings between the plurality of discontinuous metal blocks are the same.

12. The method of claim 10, wherein sizes of the plurality of discontinuous metal blocks are the same.

13. The method of claim 10, wherein spacings between the plurality of discontinuous metal blocks are different.

14. The method of claim 10, wherein sizes of the plurality of discontinuous metal blocks are different.

15. The method of claim 10, wherein the circuit layer includes a plurality of conductive circuits, and each of the plurality of conductive circuits covers portions of the plurality of discontinuous metal blocks.

16. The method of claim 10, wherein the seed layer is formed by first forming a metal layer on the dielectric layer, and then etching the metal layer to form the plurality of discontinuous metal blocks.

17. The method of claim 10, wherein the seed layer is formed by directly forming the plurality of discontinuous metal blocks on the dielectric layer.

18. The method of claim 10, further comprising: forming a patterned resist layer on the dielectric layer and the plurality of discontinuous metal blocks, wherein the patterned resist layer has a plurality of openings.

19. The method of claim 18, further comprising: forming the circuit layer by electroplating on the plurality of discontinuous metal blocks exposed from the plurality of openings in the patterned resist layer.

20. The method of claim 19, further comprising: removing the patterned resist layer and portions of the plurality of discontinuous metal blocks covered by the patterned resist layer.

21. The method of claim 10, further comprising:
forming another dielectric layer on the circuit layer;
forming another seed layer composed of a plurality of another discontinuous metal blocks on the another dielectric layer; and
forming another circuit layer on the another seed layer.

22. The method of claim 21, wherein the another circuit layer includes a plurality of another conductive circuits, and a line width/line spacing of each of the plurality of another conductive circuits is smaller than a line width/line spacing of each of the plurality of conductive circuits in the circuit layer.

23. The method of claim 22, wherein size and spacing of portions of the plurality of another discontinuous metal blocks under each of the plurality of another conductive circuits are smaller than size and spacing of portions of the plurality of discontinuous metal blocks under each of the plurality of conductive circuits.
